(19) United States
(12) Patent Application Publication
(10) Pub. No.: US 2025/0371445 A1
(43) Pub. Date: Dec. 4, 2025

(54) REINFORCEMENT LEARNING FOR GENERATION OF ROUTE-VALUE VECTORS

(71) Applicant: Veho Tech, Inc., Claymont, DE (US)

(72) Inventor: Matthew Gerard DiNardo, Cary, NC (US)

(73) Assignee: Veho Tech, Inc., Claymont, DE (US)

(21) Appl. No.: 19/227,060

(22) Filed: Jun. 3, 2025

Related U.S. Application Data
(60) Provisional application No. 63/655,992, filed on Jun. 4, 2024.

(51) Int. Cl. G06Q 10/047; G06F 30/27

(52) U.S. Cl. CPC G06Q 10/047; G06F 30/27

(57) ABSTRACT

A method may include generating, by a reinforcement agent, an offer including a route and an offer amount, evaluating, using a simulated delivery driver within a simulated environment, the generated offer to accept or reject the generated offer, responsive to the simulated delivery driver accepting or rejecting the generated offer, updating a state of the simulated environment, and providing a reward to the reinforcement agent based on the state of the simulated environment.

### CROSS-REFERENCE TO RELATED APPLICATIONS

This application claims priority to U.S. Provisional Patent Application No. 63/655,992, filed Jun. 4, 2024, which application is incorporated herein by reference in its entirety.

### BACKGROUND

Incentivizing independent contractors to fulfill tasks can be a difficult process, requiring balancing task completion against cost of completion. Conventional systems generally increase incentive amounts in order to increase task completion, which can lead to delayed and overpriced task completion.

### SUMMARY

Various aspects of the disclosure may now be described with regard to certain examples and embodiments, which are intended to illustrate but not limit the disclosure. Although the examples and embodiments described herein may focus on, for the purpose of illustration, specific systems and processes, one of skill in the art may appreciate the examples are illustrative only, and are not intended to be limiting.

Offers may be presented to delivery drivers to deliver a set number of packages for a set price. The offers may be generated based on a predicted duration of a delivery route for the set number of packages. The offers can be presented to multiple different delivery drivers simultaneously, or presented in a marketplace of offers for acceptance by the delivery drivers. Embodiments discussed herein provide for training and deploying machine-learning models to automatically generate offers to present to drivers to increase task completion and reduce cost of task completion. The machine-learning models can be trained using reinforcement learning using simulated driver behavior and/or historical driver behavior in order to accurately predict how delivery drivers will respond to different offers and to generate offers that will be accepted by delivery drivers. In this way, the machine-learning models can generate offers that strike an optimal balance between task completion (i.e., completion of all delivery routes) and cost of task completion (i.e., cost of delivery).

The foregoing summary is illustrative only and is not intended to be in any way limiting. In addition to the illustrative aspects, embodiments, and features described above, further aspects, embodiments, and features may become apparent by reference to the following drawings and the detailed description.

### BRIEF DESCRIPTION OF THE DRAWINGS

FIG. 1 is a block diagram of an example system for coordinating package delivery.

FIG. 2 is a block diagram of an example system for generating package delivery offers.

FIG. 3 is a block diagram of an example system for training an offer generator.

FIG. 4 is a flow diagram of an example method for training an offer generator.

FIG. 5A is an example user interface at a first time for training and/or deploying an offer generator.

FIG. 5B is the user interface of FIG. 5A at a second time.

FIG. 6A is an example user interface at a first time for training and/or deploying an offer generator.

FIG. 6B is the user interface of FIG. 6A at a second time.

FIG. 7 is an example chart showing market clearance performance of a trained offer generator relative to a baseline.

FIG. 8 is an example chart showing price performance of a trained offer generator relative to a baseline.

FIG. 9 is a flow diagram of an example method for training a reinforcement agent to generate package delivery offers using simulated delivery drivers.

The foregoing and other features of the present disclosure may become apparent from the following description and appended claims, taken in conjunction with the accompanying drawings. Understanding that these drawings depict only several embodiments in accordance with the disclosure and are therefore, not to be considered limiting of its scope, the disclosure may be described with additional specificity and detail through use of the accompanying drawings.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It may be readily understood that the aspects of the present disclosure, as generally described herein, and illustrated in the figures, may be arranged, substituted, combined, and designed in a wide variety of different configurations, all of which are explicitly contemplated and made part of this disclosure.

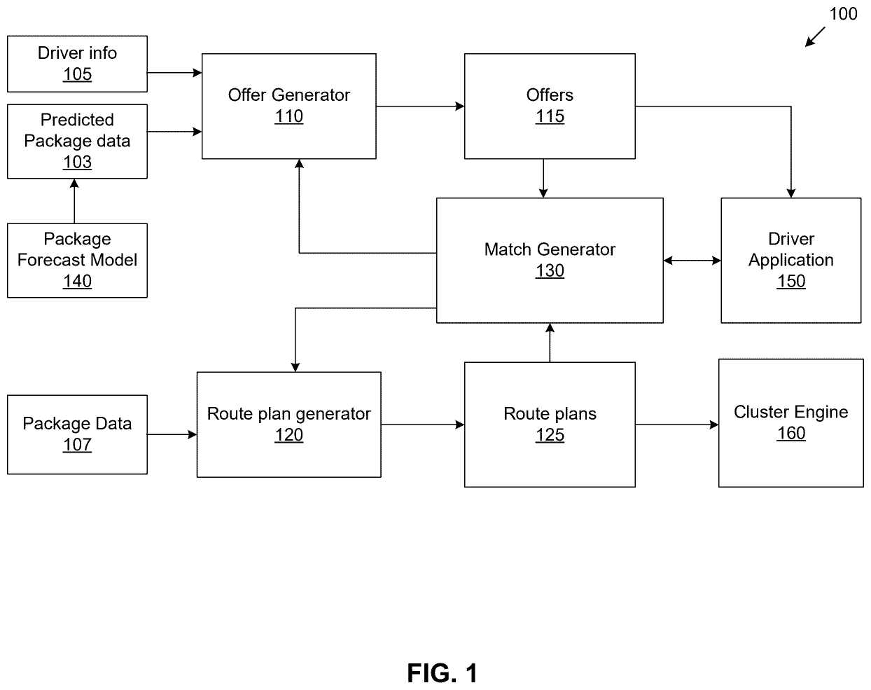

FIG. 1 is a block diagram of an example system 100 for coordinating package delivery. The system 100 includes an offer generator 110. The offer generator 110 may be a machine-learning model trained to generate offers 115. The offers 115 may be driver-facing offers to deliver packages. The offers 115 may each include one or more of a region, price, duration, and a number of packages. In some implementations, the offers 115 each one or more of a range of potential prices, a range of potential durations, and/or a range of a potential number of packages.

The offer generator 110 may receive as input predicted package data 103 and output the offers 115. The predicted package data 103 may include a prediction of one or more of a number of packages, destinations for packages, sizes of packages, and weights of packages. The predicted package data 103 may be based on historical package data as well as additional data such as weather, seasonal trends, and economic indicators. The predicted package data 103 may include predicted package volume for a future time period, before actual package volume is known. In some implementations, the predicted package data 103 may be generated by a package forecast model 140. The package forecast model 140 may be a machine-learning model. The package forecast model 140 may be trained using historical package data and/or additional data such as weather, seasonal trends, and economic indicators to generate the predicted package data 103. In an example, the package forecast model 140 is trained using a supervised training approach in which the package forecast model 140 is executed using as input historical data to generate a predicted package volume for a time period which is compared to an actual package volume for the time period. In this example, the package forecast model 140 is updated based on a difference between the predicted package volume and the actual package volume.

In some implementations, the offer generator 110 receives as input the predicted package data 103 as well as driver information 105. The driver information 105 may include driver vehicle information, such as vehicle size, vehicle height, vehicle capacity (e.g., in cubic feet), and other vehicle characteristics. In an example, the offer generator 110 receives as input the predicted package data 103 and vehicle capacity information and generates the offers 115 based on how many packages of the predicted package data 103 can fit in driver vehicles. The driver information 105 may include a ratio of successful deliveries performed by a driver, a delivery speed of the driver, a starting location of the driver, and/or prices of offers previously accepted by the driver.

The offer generator 110 may be trained using historical data. In an example, the offer generator 110 may be executed using as input historical data to generate offers for a historical time period, which offers are compared to actual, human-generated offers for the historical time period. In this example, the offer generator 110 is updated based on a difference between the generated offers for the historical time period and the actual offers for the historical time period. In some implementations, the offer generator 110 may be trained based on an acceptance rate of the offers 115. In an example, the offer generator 110 may be trained based on a speed at which the offers 115 are accepted. In an example, the offer generator 110 may be trained based on whether the offers 115 are accepted quickly enough to ensure timely delivery of packages.

The offers 115 may be provided to drivers using a driver application 150. The driver application 150 may a computer application (e.g., mobile application) which provides a user interface for drivers to view and accept the offers 115. The driver application 150 may display the offers 115 including prices, ranges of prices, region, numbers of packages, ranges of number of packages, durations, or ranges of durations. The drivers may, using the driver application 150, accept offers for current and/or future time periods. In an example, a driver accepts, using the driver application 150, an offer to deliver packages the same day when the packages are to be delivered. In an example, a driver accepts, using the driver application 150, an offer to deliver packages three days before when the packages are to be delivered. In an example, a driver accepts, using the driver application 150, an offer to deliver packages one week before when the packages are to be delivered.

The system 100 includes a route plan generator 120. The route plan generator 120 may be a machine-learning model which is executed using as input package data 107 to generate route plans 125. The package data 107 may be actual package data including a number of packages, delivery destinations of the packages, sizes and weights of the packages, and other package characteristics. The package data 107 may be received from a variety of sources. In an example, the package data 107 may be received using API calls from a plurality of merchants which need packages delivered, the API calls ingested to produce the package data 107 as input to the route plan generator 120. The route plans 125 may be routes through a delivery region. The route plans 125 may include routes for delivery drivers to take in delivering packages. The route plans 125 may be associated with packages of the package data 107 or generated based on the package data 107 but not associated with any specific packages of the package data 107. The route plans 125 may include break points representing points in the route plans where the route plans may be broken into smaller route plans if needed. In this way, portions of route plans may be moved between different route plans, providing flexibility in how packages are to be delivered.

The route plan generator 120 may receive as input the package data 107 and output the route plans 125. The route plan generator 120 may optimize the route plans 125 based on package density (e.g., density of deliveries in an area) and distance from a pickup location (e.g., distance from a warehouse where drivers pick up packages).

The route plan generator 120 may be trained to generate and optimize the route plans 125 using a supervised or semi-supervised training approach. The route plan generator 120 may be trained using historical data. In an example, the route plan generator 120 may be executed using historical data to generate route plans for a historical period which are compared to actual route plans (e.g., human-generated route plans) used for the historical period. In this example, the route plan generator 120 is updated based on a difference between the actual route plans and the generated route plans. The route plan generator 120 may be updated based on delivery statistics. In an example, the route plan generator 120 generates the route plans 125, the route plans 125 are used by drivers to deliver packages, and delivery times of the packages are used to update the route plan generator 120. In this example, the route plan generator 120 may be updated, using the delivery times of the packages, to better optimize the route plans for time between stops as well as a total delivery time for the packages.

The route plan generator 120 may begin to generate the route plans 125 once the package data 107 begins to be received. The route plan generator 120 may dynamically generate and update the route plans 125 as the package data 107 is received. The offer generator 110 may begin to generate the offers 115 before the package data 107 begins to be received. The offer generator 110 may begin to generate the offers once the predicted package data 103 is generated/received. In this way, the offers 115 may be generated before the route plans 125. The offers 115 and route plans 125 may be dynamically generated and updated until package assignments are finalized and/or until drivers pick up the packages for delivery. In this way, the offers 115 may begin to be generated before the route plans 125 begin to be generated, and the offers 115 and the route plans 125 may be dynamically generated and updated until package assignments are finalized and/or until drivers pick up the packages for delivery.

The system 100 includes a match generator 100. The match generator 100 may be a machine-learning model which is executed using as input the offers 115 and the route plans 125 to generate pairs of offers and route plans. The offer and route plan pairs generated by the match generator 130 may include an offer of the offers 115 and one or more route plans of the route plans 125. The match generator 100 may generate the offer and route plan pairs based on characteristics of the offers 115 and the route plans 125.

The match generator 130 may be trained to generate and optimize the offer and route plan pairs using a supervised or semi-supervised training approach. The match generator 130 may be trained using historical data. The match generator 130 may be executed using a set of offers and a set of route plans to generate predicted pairs which are compared to actual pairs of the set of offers and the set of route plans (e.g., human-generated pairs). The match generator 130 may be updated based on a difference between the predicted pairs and the actual pair. In some implementations, the match generator 130 may be trained based on delivery statistics resulting from implementation by drivers of generated offer and route plan pairs. In an example, the match generator 130 is updated using delivery times and delivery durations resulting from implementation of offer and route plan pairs generated by the match generator 130. In this way, the match generator 130 can learn from historical data and/or the consequences of its own output.

The match generator 130 may pass the offer and route plan pairs and/or the route plans 125 to the offer generator 110. The offer generator 110 may dynamically generate and update the offers 115 based on the offer and route plan pairs and/or the route plans 125. The updated offers 115 may be provided as input to the match generator 130 which dynamically generates and updates the offer and route plan pairs. In this way, the offers 115 are dynamically generated and updated in a cyclical manner. Similarly, the match generator 130 may pass the offer and route plan pairs and/or the offers 115 to the route plan generator 120. The route plan generator 120 may dynamically generate and update the route plans 125 based on the offer and route plan pairs and/or the offers 115. The updated route plans 125 may be provided as input to the match generator 130 which dynamically generates and updates the offer and route plan pairs. In this way, the route plans 125 are dynamically generated and updated in a cyclical manner.

In some implementations, the offers 115, the route plans 125, and the offer and route plan pairs are updated sequentially. In an example, the offer and route plan pairs are generated, the offers 115 are updated based on the offer and route plan pairs, the offer and route plan pairs are updated based on the offers 115, and the route plans 125 are updated based on the updated offer and route plan pairs and the updated offers 115. In some implementations, the offers 115 and the route plans 125 are updated in parallel. In an example, the offer and route plan pairs are generated, the offers 115 and the route plans 125 are each updated based on the offer and route plan pairs, the offer and route plan pairs are updated based on the updated offers 115 and updated route plans 125, and so on. In some implementations, the offers 115, the route plans 125, and the offer and route plan pairs are updated using a combination of sequential and parallel updates. In this way, the offers 115, the route plans 125, and the offer and route plan pairs are dynamically generated and updated in order to improve and optimize the offers 115, the route plans 125, and the offer and route plan pairs.

In some implementations, dynamically generating and updating the offers 115 and the route plans 125 includes generating new offers 115 and/or route plans 125. In an example, if not enough offers were initially generated for the package volume of the package data 107, additional offers can be generated. In an example, if too many offers were initially generated, one or more offers can be deleted and/or one or more route plans can be split to be mapped to different offers.

Each of the offers 115, the route plans 125, and the offer and route plan pairs may be updated as soon as they are initially generated and/or as soon as updated data is available. In an example, the offers 115 may be updated based on new predicted package data 103, new driver information 105, new/updated offer and route plan pairs, and/or new/updated route plans 125. In an example, the route plans 125 may be updated based on new package data 107, new/updated offer and route plan pairs, and/or new/updated offers 115. In an example, the offer and route plan pairs may be updated based on new/updated offers 115 and/or new/updated route plans 125.

The match generator 130 may provide the offer and route plan pairs to the driver application 150. The match generator 130 may provide the offer and route plan pairs to the driver application 150 based on driver check-in and/or drivers arriving to pick up packages. In some implementations, the match generator 130 may provide the offer and route plan pairs at a predetermined time prior to the drivers arriving to pick up packages in order to inform drivers beforehand of routes they will be driving. Providing the offer and route plan pairs to the driver application 150 may include providing the route plans 125 to the driver application 150 corresponding to offers of the offers 115 which have been accepted by drivers. In an example, providing the offer and route plan pairs to the driver application 150 includes identifying a driver who accepted an offer, identifying, using the offer and route plan pairs, a route plan corresponding to the offer, and sending the route plan to the driver application 150 to be displayed to the driver. In this way, drivers can view and accept the offers 115 before the package data 107 is received and before the route plans 125 are generated, and then deliver packages according to the route plans 125 once the route plans 125 are generated and paired with the accepted offers 115.

The route plans 125 may be delivered as input to a cluster engine 160. The cluster engine 160 may generate clusters of packages based on the route plans 125. The clusters may be used to sort packages for pickup by drivers for delivery. The cluster engine 160 may dynamically update the clusters based on updates to the route plans 125. In some implementations, the dynamic generation and updating of the route plans 125 is constrained by timing requirements of the package sorting process. In this way, the route plans 125 may be dynamically generated and updated for as long as feasible, or until packages need to be physically sorted according to the clusters. The drivers may pick up packages sorted by clusters for delivery using the corresponding route plans 125.

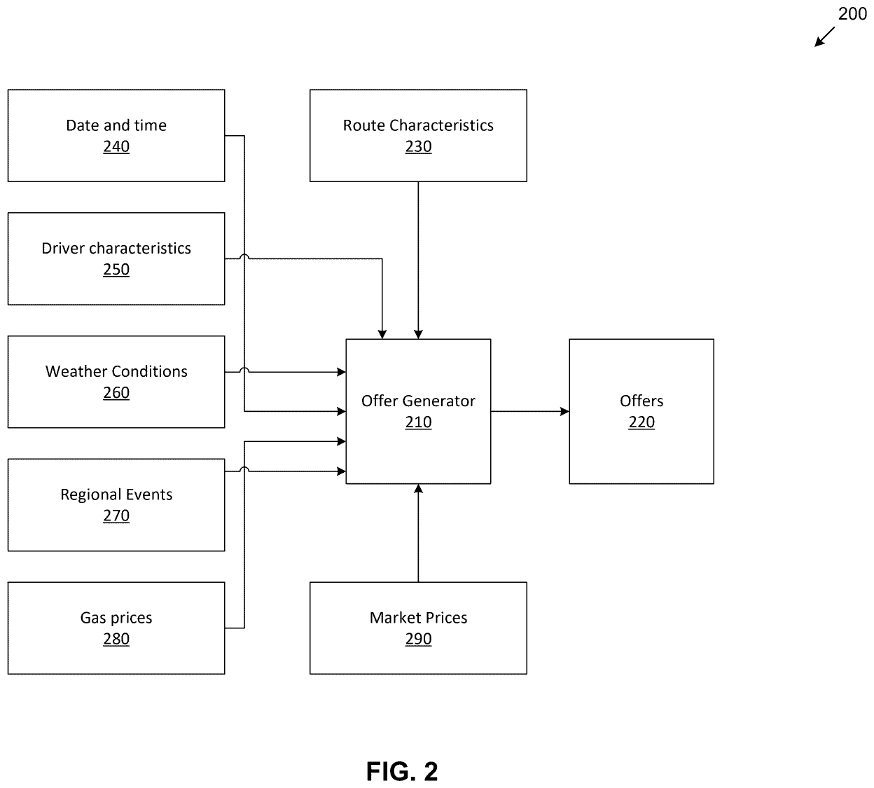

FIG. 2 is a block diagram of an example system 200 for generating package delivery offers. The system 200 includes an offer generator 210. The offer generator 210 may be the offer generator 110 of FIG. 1. The offer generator 210 may be a machine-learning model, such as a reinforcement agent, a neural network, a convolutional neural network, random forest model, and/or another type of machine-learning model.

The offer generator 210 may be executed using as input data from various sources and/or of various types to generate offers 220. As discussed herein, the offers 220 may include a delivery route for delivering a set number of packages as well as a monetary reward for completing the delivery route.

The input received by the offer generator 210 may include route characteristics 230, such as a length of the route, an expected duration of the route, a geographic are of the route, a distance of the route from a package pickup location, a distance of the route from a location of a delivery driver, road conditions along the route, speed limits along the route, school zones along the route, toll roads along the route, and/or other characteristics of the route.

The input received by the offer generator 210 may include a date and time 240. The date and time 240 can include a current date and time as well as a date and time of the route. In an example, the date and time 240 includes the current date and time such that the offer generator 210 can take into account driver behavior at certain times of day and on certain days of the week as well as an amount of time before the route needs to be completed. In an example, the date and time 240 includes the date and time of the route such that the offer generator 210 can take into account driver willingness to execute the route at the date and time of the route. In an example, drivers may be more willing to deliver packages in the morning than late at night.

The input received by the offer generator 210 may include driver characteristics 250. The driver characteristics can include driver preferences, a driver vehicle type, a driver's historical routes and associated offers, a driver's historical delivery performance, a driver's number of routes performed, a driver's historical app usage (e.g., when the driver checks a driver application for offers such as the driver application 150), and other driver characteristics. In some implementations, the offer generator 210 can generate offers specific to drivers. In some implementations, the offer generator 210 can generate offers for all drivers based on characteristics of drivers that are likely to view offers generated by the offer generator 210.

The input received by the offer generator 210 may include weather conditions 260. The weather conditions 260 can include current weather conditions and/or weather conditions expected on the delivery route. In an example, the weather conditions 260 include current weather conditions such that the offer generator 210 can take into account current expected driver behavior (e.g., drivers reluctant to accept offers when it is raining, or drivers eager to accept offers when it is sunny). In an example, the weather conditions 260 include weather conditions expected on the delivery route such that the offer generator 210 can take into account how the weather conditions will affect the duration of the route and/or the driver's willingness to complete the route (e.g., drivers drive slower in rain, drivers less willing to complete routes in snow).

The input received by the offer generator 210 may include regional events 270. The regional events 270 may include local concerts, sporting events, holidays, lunar eclipses, and other events that may affect traffic patterns and/or an availability of delivery drivers. In this way, the offer generator 210 can adjust offers to adapt to the regional events 270. In an example, the offer generator 210 increases offer amounts in response to a holiday to increase a likelihood that delivery drivers accept the corresponding offers. In an example, the offer generator 210 increases offer amounts in response to a local concert to compensate drivers for delivering in difficult traffic conditions and to increase a likelihood that delivery drivers accept the corresponding offers.

The input received by the offer generator 210 may include gas prices 280 such that the offer generator 210 can take into account a cost incurred by delivery drivers in completing the delivery routes and/or a willingness of the drivers to accept the offers. The offer generator 210 can be executed using as input other commodity prices, allowing the offer generator 210 to adapt the offers 220 to price inflation and other factors.

The input received by the offer generator 210 may include market prices 290 such as offers to perform other kinds of work. The market prices 290 may include a prevailing wage at local businesses and/or current offers for contract work or gig work, such as ride share services, food delivery services, and other offer-based work. In this way, the offer generator 210 can adapt the offers 220 based on competing offers and/or driver willingness to accept the offers 220 relative to other work.

The offer generator 210 can be executed using as input any combination or weighted combination of the route characteristics 230, the date and time 240, the driver characteristics 250, the weather conditions 260, the region events 270, the gas prices 280, and the market prices 290 to generate the offers 220. Weights may be applied to the various inputs to the offer generator 210 to affect an importance or attention afforded to the various inputs.

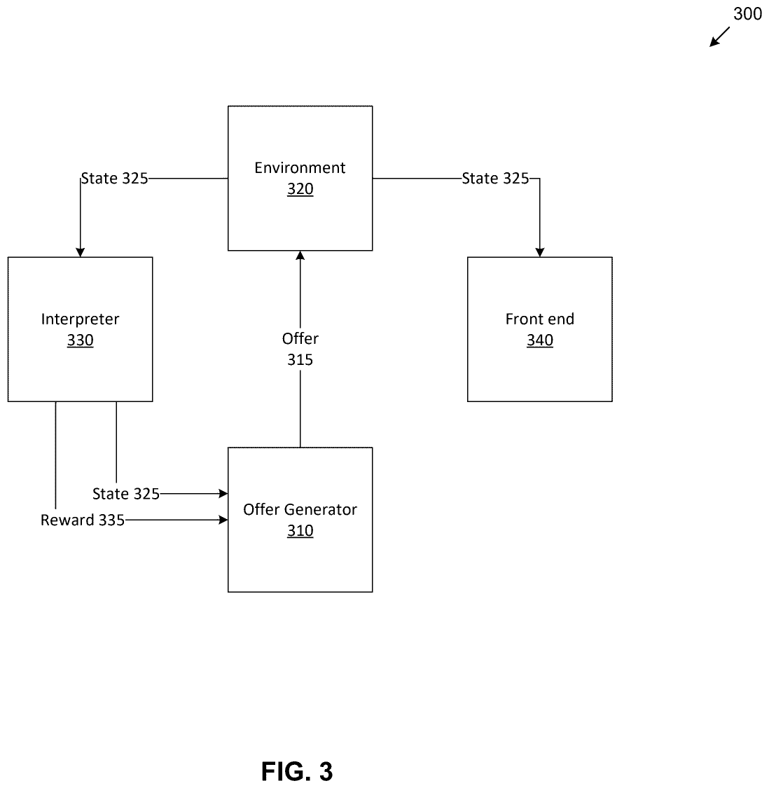

FIG. 3 is a block diagram of an example system 300 for training an offer generator 310. The system 300 may be a system for training the offer generator 310 using a reinforcement environment 320. The offer generator 310 may be the offer generator 210 of FIG. 2.

The offer generator 310 generates an offer 315 which is provided to the environment 320. The environment 320 has a state 325 which is updated based on the offer 315. In an example, the environment 320 includes a set of routes, a set of simulated drivers, a time of day, and a level of market clearance (i.e., percentage of routes accepted in offers by drivers). The offer 315 generated by the offer generator 310 includes a route of the set of routes and an offer amount. The offer generator 310 can generate offers 315 based on the state 325 of the environment 320. In some implementations, the offer generator 310 can analyze the state 325, which may include information such as the current set of available routes, driver availability, time of day, and market clearance levels. The offer generator 310 can use this information to determine an appropriate route and offer amount for the offer 315. For example, the offer generator 310 may adjust the offer amount based on the current market clearance level, increasing the amount if market clearance is low to incentivize more driver acceptances.

The environment 320 includes a plurality of simulated delivery drivers, each having distinct characteristics that influence offer acceptance decisions. A set of simulated drivers can be selected from the plurality of simulated delivery drivers to evaluate the offer 315 based on various selection criteria, such as driver availability, time of day, or geographic location. Each simulated driver in the set of simulated drivers can have specific characteristics including a floor price below which the simulated driver will not accept offers, sensitivity to weather conditions, responsiveness to gas prices, preferred working hours, vehicle capacity limitations, or historical acceptance patterns, among others. In some implementations, the set of simulated drivers can be selected using a probabilistic model that determines which drivers are likely to be evaluating offers at a particular time step in the simulated environment 320. The characteristics of each simulated driver can be used to determine whether the simulated driver accepts the offer 315. For example, a simulated driver with a floor price of $25 per hour may reject an offer with an amount of $23 per hour regardless of other factors. In an example, a simulated driver with high sensitivity to weather conditions may reject an otherwise acceptable offer during simulated rain or snow conditions. In an example, a simulated driver with high sensitivity to gas prices may require a higher offer amount when simulated gas prices are elevated. The environment 320 can use the characteristics of the set of simulated drivers to generate realistic responses to the offer 315, with some simulated drivers accepting the offer 315 and others rejecting the offer 315 based on the specific characteristics of each simulated driver and the details of the offer 315.

The offer generator 310 can take into account various factors to generate the offer 315, similar to the offer generator 210 of FIG. 2. In some implementations, the offer generator 310 can consider route characteristics, date and time information, driver characteristics, weather conditions, regional events, gas prices, and market prices, among others, when generating the offer 315. The environment 320 can simulate driver responses to the offer 315 based on these same factors. For example, the offer generator 310 may adjust the offer amount based on current gas prices, while a simulated driver in the environment 320 may evaluate the offer 315 considering their own simulated sensitivity to gas prices. In an example, the offer generator 310 may generate the offer 315 taking into account expected weather conditions for a route, and the simulated drivers in the environment 320 may accept or reject the offer 315 based on their individual simulated weather sensitivities. By incorporating these shared factors, the system 300 can provide a realistic simulation of the offer generation and acceptance process, allowing the offer generator 310 to learn and adapt to various conditions that may influence both offer creation and driver decision-making.

The environment 320 provides the state 325 of the environment 320 to an interpreter 330 that evaluates the state 325 to determine a reward 335 for the offer generator 310. The reward 335 may include a reward and/or a punishment for the offer generator 310. In an example, the reward 335 includes a punishment for failure to clear the market and a reward for acceptance of offers with prices below a baseline. In an example, the reward 335 includes a reward for clearing the market and a punishment for generating offers with prices above a baseline. The reward 335 may include any combination of reward and punishment for the offer generator 310. The interpreter 330 provides the state 325 and the reward 335 to the offer generator 310 to update the offer generator 310.

The interpreter 330 can generate rewards based on multiple factors to train the offer generator 310 to produce offers that effectively clear the market while optimizing costs. In some implementations, the interpreter 330 can evaluate the state 325 of the environment 320 at each time step of the simulation to calculate the reward 335. The interpreter 330 can consider the percentage of routes accepted in offers, the prices of the offers, and the current time step to determine an appropriate reward or punishment. For example, the interpreter 330 can assign a higher reward value if a larger percentage of routes are accepted early in the simulation, encouraging the offer generator 310 to create attractive offers quickly. The interpreter 330 can also factor in the prices of accepted offers, potentially reducing the reward if the offer prices are significantly above a predetermined baseline. In an example, if 80% of routes are accepted within the first 30% of time steps, and the average offer price is within 5% of the baseline, the interpreter 330 can generate a substantial positive reward. Conversely, if only 40% of routes are accepted by the midpoint of the simulation, the interpreter 330 can generate a negative reward or punishment to encourage more aggressive offer generation. The interpreter 330 can also implement a time-decay factor, where the potential reward for accepting routes decreases as the simulation progresses, incentivizing the offer generator 310 to clear the market efficiently. In some implementations, the interpreter 330 can use a weighted combination of these factors to calculate the reward 335. For instance, the interpreter 330 can assign a weight of 0.5 to the percentage of accepted routes, 0.3 to the average offer price relative to the baseline, and 0.2 to the time step of acceptance. This weighting can be adjusted based on the specific goals of the training process, such as prioritizing market clearance over cost optimization or vice versa.

The offer generator 310, as updated by the state 325 and the reward 335, generates an additional offer 315 and provides the additional offer 315 to the environment 320. In this way, the offer generator 310 is iteratively updated based on the reward 335 from the interpreter 330 based on the state 325 of the environment 320. Iterations of generating the offer 315 and providing the reward 335 to the offer generator 310 may be reflected as time steps in the environment 320. In an example, the offer generator 310 generates a set number of offers for each time step in the environment 320. The state 325 of the environment 320 may reflect the time steps of the environment. In an example, the state 325 includes a time of day, with market clearance required by an end of the day.

The offer generator 310 can be updated based on the reward 335 between each time step of the simulation and/or at the end of the simulation according to the final state 325 of the simulation. In some implementations, the offer generator 310 can use the reward 335 to adjust its internal parameters, such as weights assigned to different input factors or decision thresholds, after each time step. For example, if the reward 335 indicates that the offer generator 310 is consistently generating offers that are too low to be accepted, the offer generator 310 can increase the weight given to factors that influence offer amounts, such as gas prices 280 or market prices 290. In some implementations, the offer generator 310 can accumulate rewards over multiple time steps and perform a batch update at predetermined intervals or at the end of the simulation. This approach can allow the offer generator 310 to capture longer-term trends and avoid overreacting to short-term fluctuations in the environment 320. The offer generator 310 can use various machine learning techniques, such as gradient descent or reinforcement learning algorithms, to update its internal model based on the accumulated rewards. For example, the offer generator 310 can use a policy gradient method to adjust its offer generation strategy in a direction that maximizes the expected cumulative reward over the course of the simulation. In some implementations, the offer generator 310 can maintain a memory of past states, actions, and rewards, allowing the offer generator 310 to learn from historical data and improve its performance over multiple simulations.

The offer generator 310 can be trained over the course of multiple different simulations, each with varying simulated drivers and input factors. In some implementations, the offer generator 310 can be exposed to a diverse set of simulated environments 320, where each environment 320 may have a unique combination of simulated drivers, route characteristics, weather conditions, gas prices, and market prices, among others. The offer generator 310 can generate offers 315 for each simulation, and the interpreter 330 can provide rewards 335 based on the performance of the offer generator 310 in each specific environment 320. By iterating through multiple simulations, the offer generator 310 can learn to adapt its offer generation strategy to a wide range of scenarios. For example, one simulation may focus on a high-demand, low-driver availability scenario, while another may simulate a low-demand, high-driver availability situation. The offer generator 310 can accumulate knowledge from these varied experiences, adjusting its internal parameters to optimize performance across different conditions. In some implementations, the system 300 can gradually increase the complexity of the simulations, starting with simplified environments and progressing to more realistic and challenging scenarios. This progressive training approach can allow the offer generator 310 to build a robust understanding of the offer generation task, potentially improving its ability to generalize to real-world conditions.

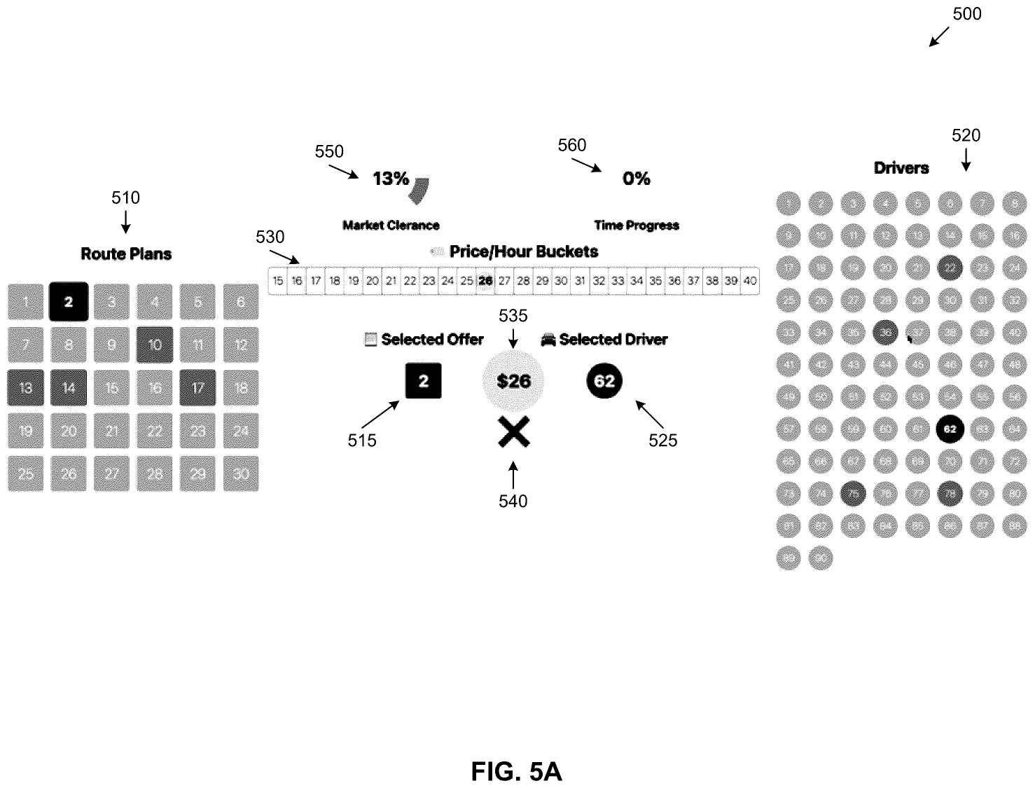

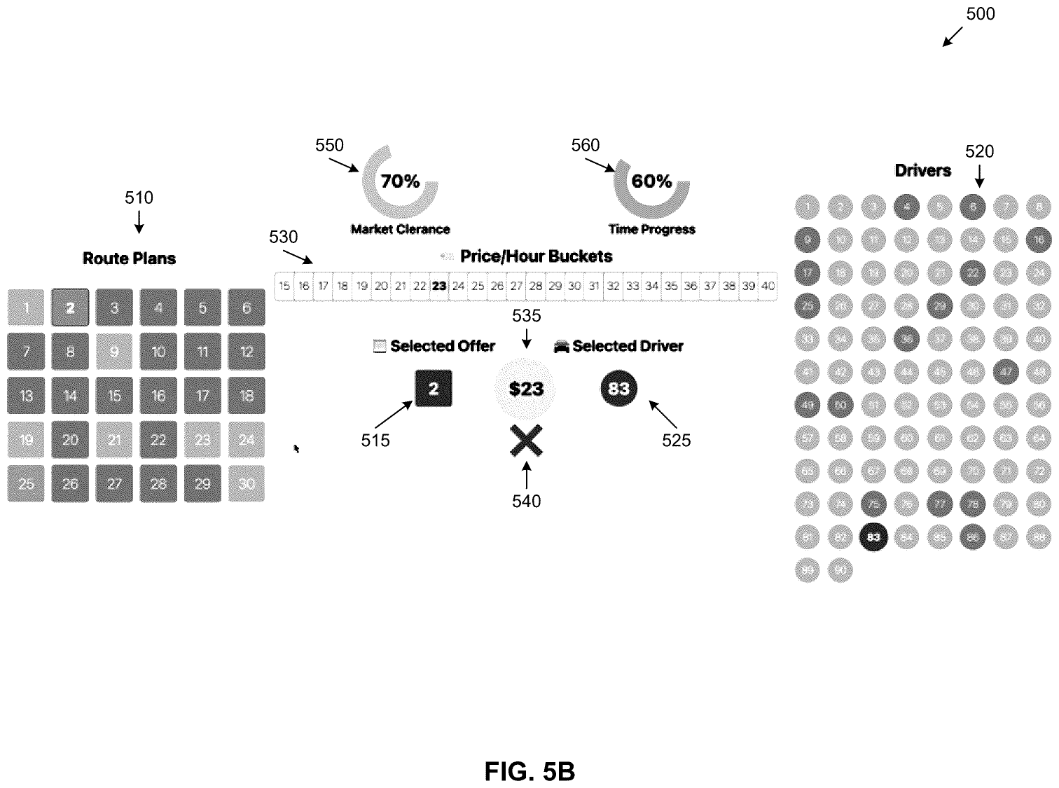

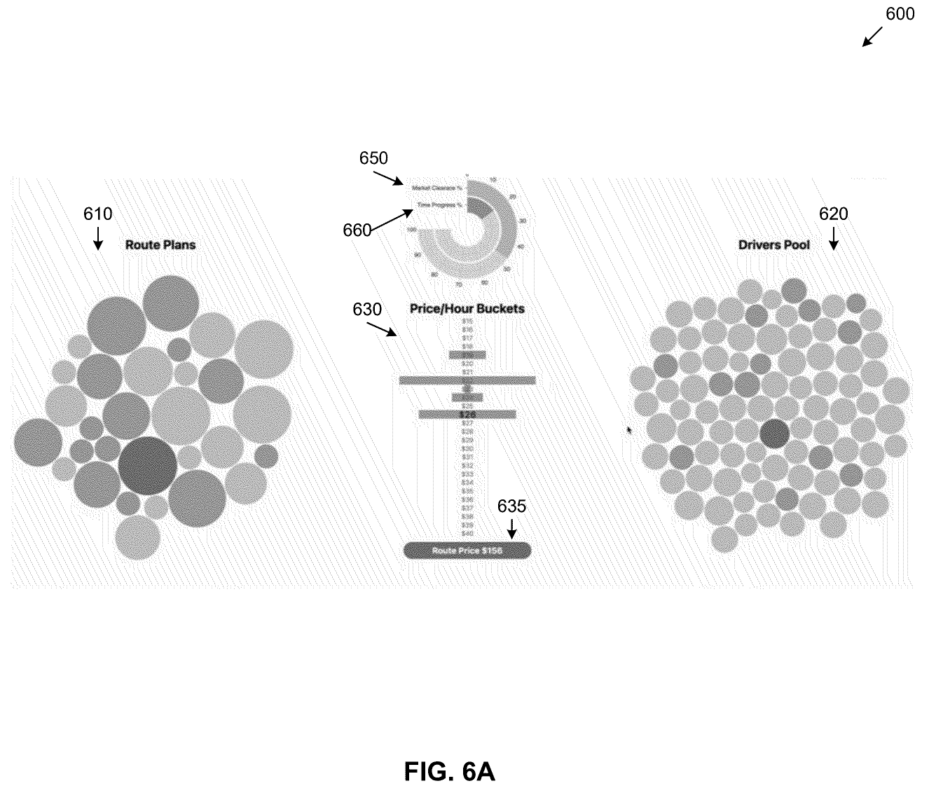

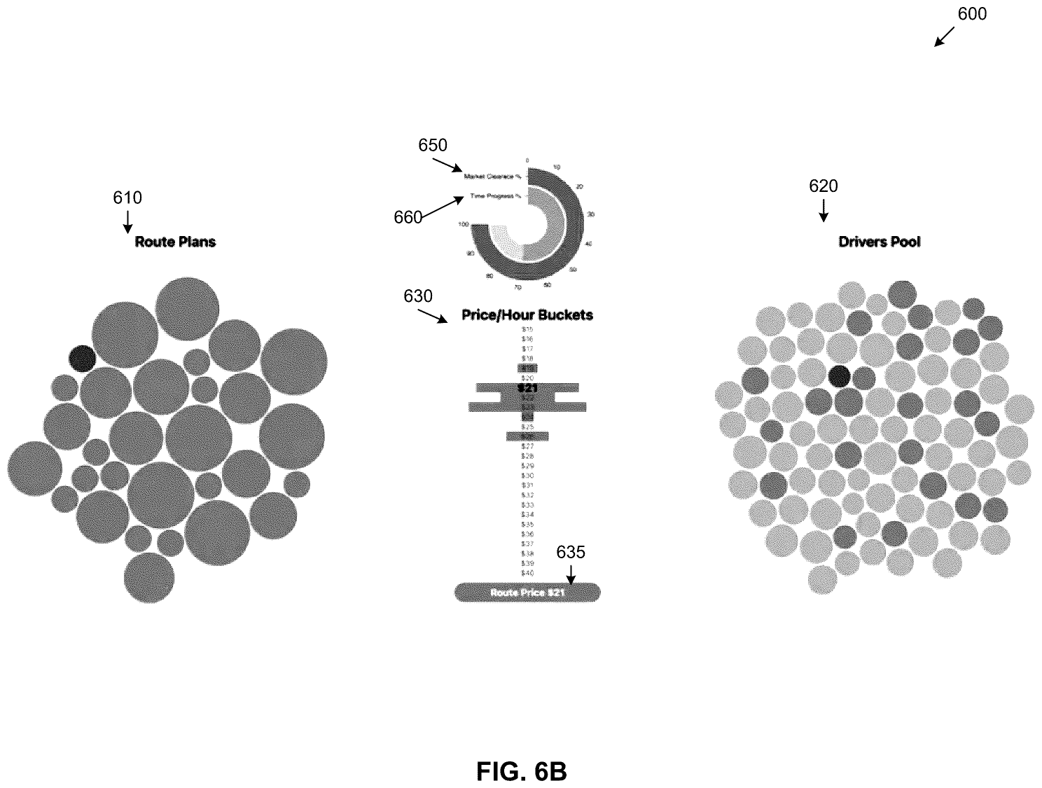

In some implementations, the environment 320 provides the state 325 of the environment 320 to a front end 340. The front end 340 may display one or more aspects of the environment 320. Examples of the front end 340 are illustrated in FIGS. 5A-6B.

While various examples describe the environment 320 as including simulated drivers, the environment 320 may include real drivers that accept actual offers from the offer generator 310. In some implementations, the offer generator 310 is initially trained using simulated drivers in a simulated environment 320 and then deployed in a real environment 320. The offer generator 310 may be updated based on performance of the offer generator 310 in the real environment 320, with the interpreter 330 continuing to evaluate the state 325 of the environment 320.

In some implementations, the interpreter 330 is part of the environment 320 such that the environment 320 sends the state 325 and the reward 335 to the offer generator 310.

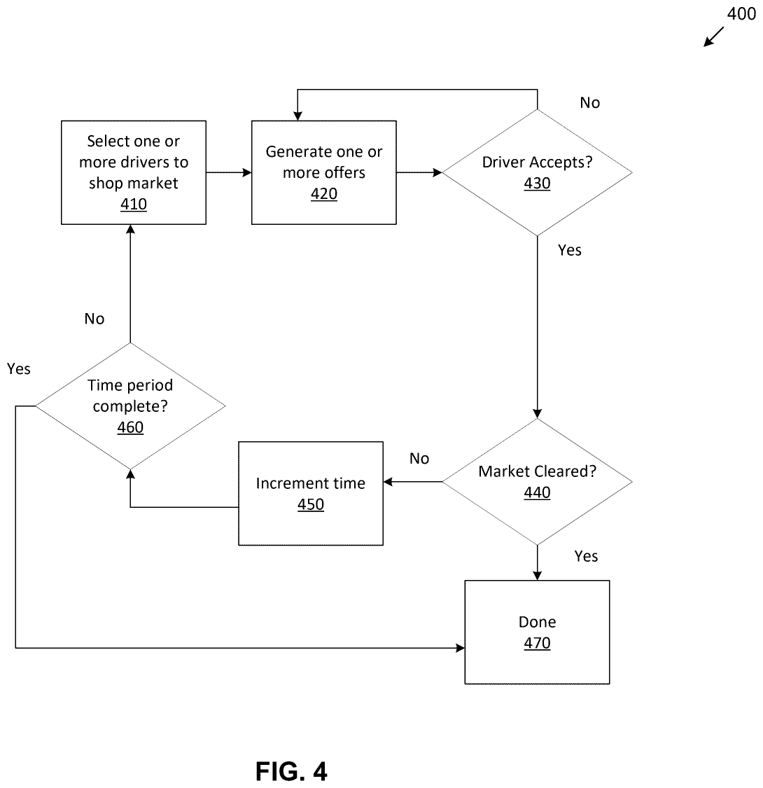

FIG. 4 is a flow diagram of an example method 400 for training an offer generator. The method 400 may include more, fewer, or different operations than shown. The operations may be performed in the order shown, in a different order, or concurrently. The method 400 may be used to train the offer generator 310 of FIG. 3 and/or the offer generator 210 of FIG. 2.

At operation 410, one or more drivers are selected to shop the market. The market may be a market of one or more offers, where each offer includes a route and an offer amount. The one or more drivers may be simulated drivers that are selected to evaluate the one or more offers.

In some implementations, the selection of one or more drivers at operation 410 can simulate drivers checking a mobile application or online portal to review offers. The method 400 can use a probabilistic model to determine which drivers from a pool of simulated drivers are likely to access the offer platform at a given time. For example, the probabilistic model can take into account factors such as time of day, day of the week, or historical patterns of driver activity to simulate realistic driver behavior. The method 400 can include generating a random number for each simulated driver and comparing the random number to a threshold value derived from the probabilistic model. Drivers whose random numbers exceed the threshold can be selected to “shop the market” in the current iteration. This approach can provide a dynamic and realistic simulation of driver engagement with the offer platform, as different drivers may be selected in each iteration based on the evolving state of the simulated environment. In some implementations, the method 400 can also consider driver-specific characteristics, such as preferred working hours or frequency of checking for offers, to further refine the selection process. By simulating this aspect of driver behavior, the method 400 can train the offer generator to adapt to varying levels of driver engagement and availability throughout the simulated time period.

At operation 420, the one or more offers are generated (e.g., generated by the offer generator 310 of FIG. 3 or the offer generator 210 of FIG. 2). In some implementations, one or more offers are generated for each driver of the one or more drivers. In some implementations, the method 400 includes generating multiple offers at operation 420 for presentation to a single simulated driver. For example, the offer generator 310 can create a set of three distinct offers, each with different route and price combinations, to be evaluated by the selected driver. This approach can simulate a real-world scenario where a mobile application presents multiple concurrent offers to drivers for consideration. The simulated driver can evaluate these offers simultaneously, comparing factors such as route length, estimated completion time, and offer price, among others. By presenting multiple offers to a single driver, the method 400 can more accurately model how drivers interact with a marketplace-style interface, where they can browse and compare various delivery opportunities before making a selection. Multiple offers can be generated and evaluated by each of the one or more drivers. In some implementations, the same offers are presented to each of the one or more drivers. In this way, the method 400 can simulate presentation of the same offers in a mobile app to all drivers who check the mobile app at the same time. In some implementations, different offers are generated and presented to each of the one or more drivers. In this way, the method 400 can simulate presentation of driver-specific offers to each driver who checks the mobile app at the same time.

For each offer of the one or more offers, a determination is made at operation 430 as to whether a driver of the one or more drivers accepts the offer. In some implementations, when a driver accepts an offer, the method 400 can remove both the driver and the route of the accepted offer from further consideration in the current iteration. For example, if a driver accepts an offer to deliver packages on a Monday afternoon, the method 400 can update the simulated environment to reflect that the driver is no longer available for additional offers during that time period. The offer generator 310 can adjust its subsequent offer generation based on the reduced pool of available drivers and remaining unassigned routes. In an example, if Driver A accepts an offer to deliver packages from 2 PM to 5 PM on a Monday afternoon, the method 400 can prevent Driver A from being presented with or accepting any other offers that overlap with this time slot on the same Monday afternoon. This approach can help simulate real-world constraints on driver availability and ensure that the offer generator 310 learns to efficiently allocate drivers and routes without overbooking.

In some implementations, when an offer is not accepted by any driver, the route included in the offer remains in the set of routes that need to be assigned. The method 400 can maintain a set of unassigned routes throughout the simulation, updating the set based on offer acceptances and rejections. For example, if an offer for a route from downtown to the suburbs is not accepted by any driver during a time step, the method 400 can retain the route in the pool of unassigned routes for subsequent offer generation attempts. The time steps of the simulation can simulate acceptance or non-acceptance of offers within a predetermined time period, such as a day or a week. In an example, each time step can represent a 15-minute interval within an 8-hour time period, allowing the offer generator 310 to adjust its strategy as time progresses. The method 400 can track the number of times a route has been offered and rejected, using this information to potentially adjust the offer parameters in future time steps. For instance, if a route has been rejected multiple times, the offer generator 310 may increase the offer amount or combine the route with other nearby deliveries to make the offer more attractive. By simulating multiple time steps within the predetermined time period, the method 400 can train the offer generator 310 to adapt its offer generation strategy based on the evolving state of route assignments and driver availability.

When a driver accepts an offer at operation 430, at operation 440 a determination is made as to whether the market is cleared (i.e., all routes accepted in offers). If the market is cleared, the method ends at operation 470, causing the offer generator to be updated based on the market clearance and the accepted offers. If the market is not cleared, time is incremented at operation 450. The offer generator may be updated based on the current state of the market, the current time, and/or the current accepted offers and remaining routes.

In some implementations, the offer generator 310 can generate different offers at different time steps of the method 400 to adapt to changing market conditions and driver availability. The offer generator 310 can take into account various input factors that may change over time, such as the number of remaining routes, the current market clearance rate, and the time elapsed since the start of the simulation. For example, the offer generator 310 can adjust the offer amounts based on the urgency to clear the market as the predetermined time limit approaches. In an example, the offer generator 310 can increase offer amounts for routes that have been repeatedly rejected in earlier time steps. The offer generator 310 can also consider time-dependent factors such as traffic patterns, weather conditions, or driver availability at different times of day. As the simulation progresses, the offer generator 310 can analyze the rate of market clearance and adjust its strategy accordingly. For instance, if the market clearance rate is lower than expected at the midpoint of the predetermined time limit, the offer generator 310 can generate more aggressive offers to incentivize drivers to accept routes. The offer generator 310 can also prioritize clearing certain types of routes based on their characteristics, such as distance or package volume, as the time limit approaches. By continuously adapting its offer generation strategy based on the passage of time and changing input factors, the offer generator 310 can work towards clearing the market before the end of the predetermined time limit.

At operation 460, a determination is made as to whether a time period is complete. The time period may be a time period for the routes to be accepted in offers, such as a day, or six hours. If the time period is complete, the method 400 ends at operation 470, causing the offer generator to be updated (e.g., rewarded and/or punished) based on a level of market clearance, the accepted offers, and the remaining routes. If the time period is not complete, the method 400 continues at operation 410. In this way, the offer generator iteratively generates offers for acceptance or rejection by the drivers until the market is cleared or the time period is complete. The offer generator may be updated and/or rewarded at each timestep as described in the training environment 300 of FIG. 3, or at the end of the method 400. In this way, the offer generator can learn from the acceptance and rejection of offers as well as the level of market clearance over time.

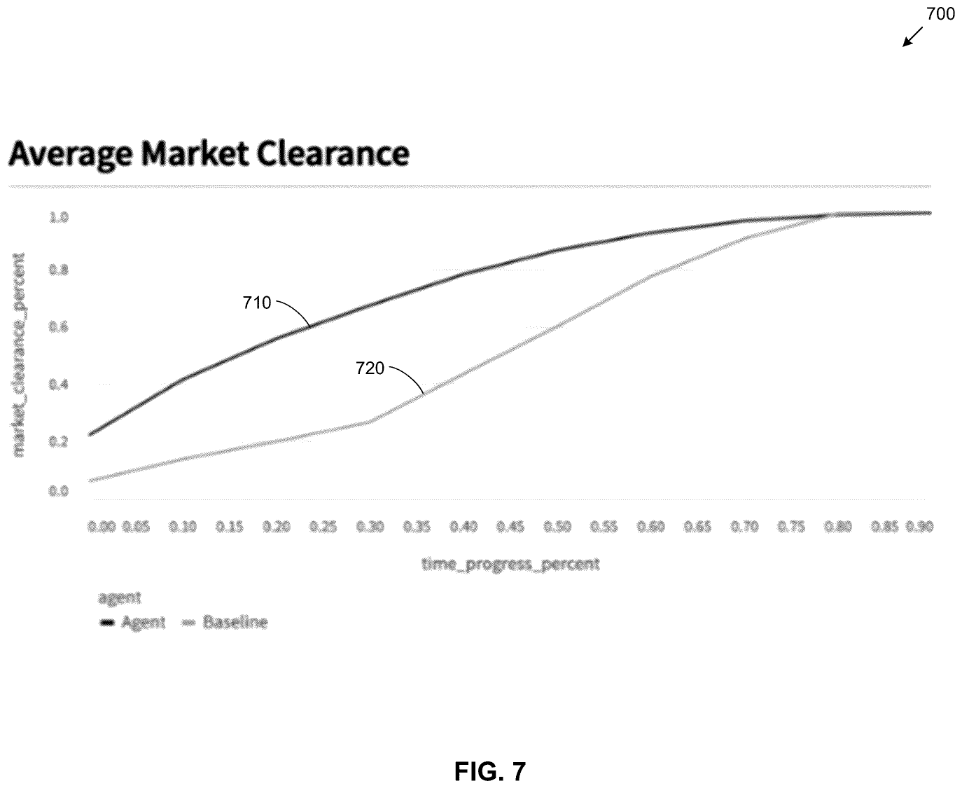

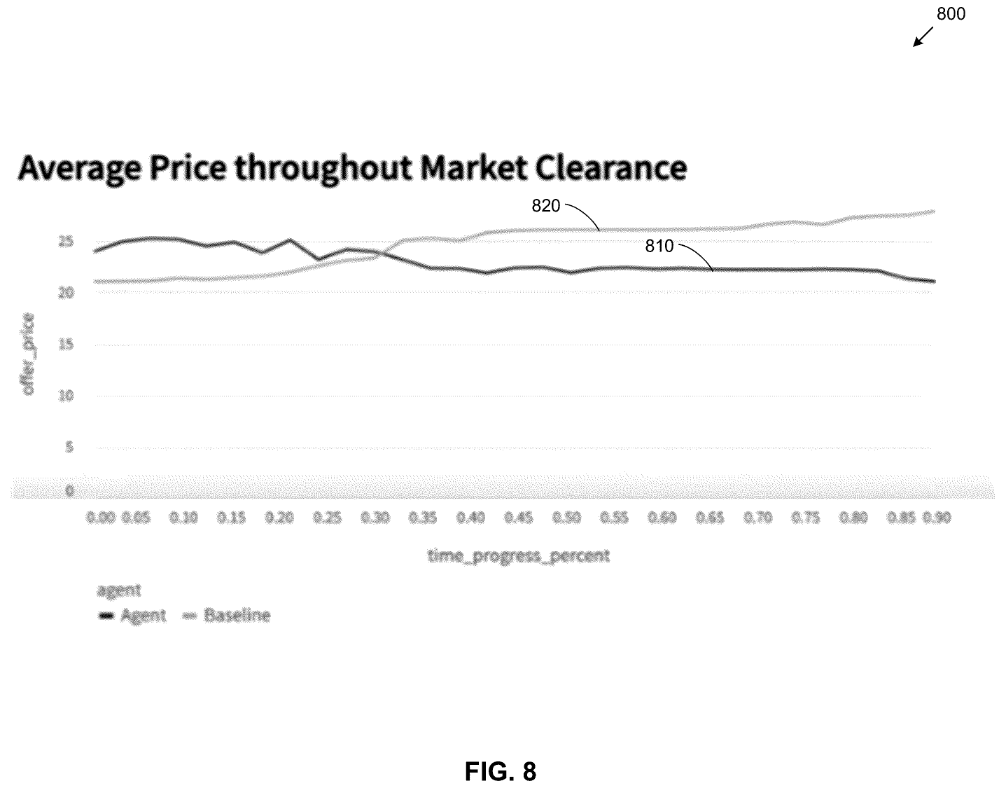

The method 400 can result in an offer generator that generates offers to optimize for both price and market clearance. Through iterative training cycles, the offer generator can learn to balance the competing objectives of maximizing market clearance while minimizing offer prices. In some implementations, the offer generator can develop strategies to clear the market efficiently by adjusting offer amounts based on factors such as time remaining, route characteristics, and driver availability. For example, the offer generator can learn to increase offer amounts strategically for routes that have been repeatedly rejected, while maintaining lower prices for routes that are more likely to be accepted. The performance of the trained offer generator can be observed in the charts presented in FIG. 7 and FIG. 8. FIG. 7 illustrates a chart 700 showing the offer generator performance 710 achieving higher market clearance rates earlier in the time period compared to the baseline performance 720. In FIG. 8, a chart 800 demonstrates how the offer generator performance 810 can maintain competitive pricing throughout the market clearance process, with offer amounts fluctuating strategically to balance market clearance and cost efficiency. The offer generator performance 810 can show lower average prices compared to the baseline performance 820 during certain periods, indicating the offer generator's ability to clear the market at potentially reduced costs. These performance metrics can demonstrate the offer generator's capacity to adapt its offer generation strategy to optimize for both market clearance efficiency and pricing effectiveness.

While the method 400 has been described in terms of simulated drivers, the method 400 can be applied to updating the offer generator using real drivers and real offers, with operation 450 of incrementing time occurring naturally. In some implementations, the method 400 can be applied to a live, implemented offer generator that generates offers for real-world drivers. The offer generator can receive real-time data inputs, such as current driver locations, traffic conditions, time of day, weather conditions, and package delivery requests, to generate offers for actual delivery routes. For example, the offer generator can analyze the current pool of available drivers and outstanding delivery requests to create optimized offers that balance driver preferences, route efficiency, and market clearance objectives. The method 400 can adapt to real-world scenarios by continuously updating the offer generator 310 based on actual driver responses and market conditions. In an example, if a particular offer is consistently rejected by drivers during peak traffic hours, the offer generator 310 can adjust its strategy to increase the offer amount or modify the route to make the offer more attractive. The live implementation can leverage historical data and real-time feedback to refine the offer generation process, potentially improving both driver satisfaction and overall delivery efficiency.

FIG. 5A is an example user interface 500 at a first time for training and/or deploying an offer generator. The user interface 500 may be an example of the front end 340 of FIG. 3. The user interface 500 includes a set of routes 510, a set of drivers 520, a set of offer amount buckets 530, a current route 515, a current offer amount 535, a current driver 525, a current decision 540, a market clearance indicator 550, and a time period indicator 560.

The set of routes 510 include indications of routes, with a first visual indicator (e.g., color) showing unaccepted routes, a second visual indicator showing accepted routes, and a third visual indicator showing the current route 515. In an example, unaccepted routes are orange, accepted routes are teal, and the current route 515 is red. The set of drivers 520 include indications of drivers, with a first visual indicator (e.g., color) showing drivers that have not accepted a route, a second visual indicator showing drivers that have accepted a route, and a third visual indicator showing the current driver 525. In an example, drivers that have not accepted a route are orange, drivers that have accepted a route are blue, and the current driver 525 is red.

The set of offer amount buckets 530 may include different buckets, or options, for offer amounts measured in price per hour. This allows for a standardized measurement of offers, as different routes have different predicted durations. The price per hour may represent an offer amount divided by a number of hours in a predicted duration of a route of an offer. The set of offer amount buckets 530 may represent different options for offer amounts the offer generator can select in generating offers. In an example, the offer generator selects a route from the set of routes 510 and an offer amount bucket from the offer amount buckets 530 to generate an offer. The set of offer amount buckets 530 includes an indication of the current offer amount 535.

The current offer amount 535 shows an amount of the current offer in price per hour. The current offer amount 535 and the current route 515 represent the current offer. The current decision 540 indicates whether the current driver 525 accepts or rejects the current offer (i.e., the current route 515 at the current offer amount 535. The offer generator can generate multiple offers (i.e., multiple combinations of routes and offer amounts) to present to the current driver 525. After presenting a set number of offers to the current driver 525, the offer generator can present offers to a different driver of the set of drivers 520. The current driver 525 can be randomly selected from the set of drivers 520. The current driver 525 can be selected from the set of drivers based on a probability of the current driver 525 checking the market at the current time. The current driver 525 can be selected based on a probabilistic model that is executed using as input the current time and characteristics of the set of drivers 620 to output the current driver 525. In this way, the current driver 525 can more accurately reflect driver behavior, such as when drivers check the market.

The market clearance indicator 550 indicates a percentage of the set of routes 510 that have been accepted. The time period indicator 560 indicates a percentage of the time period that has elapsed. The offer generator can take into account the market clearance and elapsed time in generating offers.

FIG. 5B is the user interface 500 of FIG. 5A at a second time, after the first time, as reflected in the time period indicator 560. As time has progressed, a greater percentage of the set of routes 510 have been accepted, as reflected in the colors of the set of routes 510 and the market clearance indicator 550. Accordingly, a greater number of the set of drivers 520 have accepted offers, as reflected in the colors of the set of drivers 520.

FIG. 6A is an example user interface 600 at a first time for training and/or deploying an offer generator. The user interface 600 may be an example of the front end 340 of FIG. 3. The user interface 600 includes a set of routes 610, a set of drivers 620, a set of offer amount buckets 630, a current offer amount 635, a market clearance indicator 650, and a time period indicator 660.

The set of routes 610 include indications of routes, with a first visual indicator (e.g., color) showing unaccepted routes, a second visual indicator showing accepted routes, and a third visual indicator showing a current route (i.e., route in a current offer). In an example, unaccepted routes are orange, accepted routes are teal, and the current route is red. The set of routes 610 may have sizes indicating an expected duration, with routes with longer expected durations being larger than routes with shorter expected durations. The set of drivers 620 include indications of drivers, with a first visual indicator (e.g., color) showing drivers that have not accepted a route, a second visual indicator showing drivers that have accepted a route, and a third visual indicator showing a current driver (i.e., driver evaluating the current offer). In an example, drivers that have not accepted a route are orange, drivers that have accepted a route are blue, and the current driver is red. The set of drivers 620 may have sizes indicating a floor offer amount (hidden from the offer generator) above which the drivers will accept an offer.

The set of offer amount buckets 630 may include different buckets, or options, for offer amounts measured in price per hour. This allows for a standardized measurement of offers, as different routes have different expected durations. The price per hour may represent an offer amount divided by a number of hours in an expected duration of a route of an offer. The set of offer amount buckets 630 may represent different options for offer amounts the offer generator can select in generating offers. In an example, the offer generator selects a route from the set of routes 610 and an offer amount bucket from the offer amount buckets 630 to generate an offer. The set of offer amount buckets 630 includes an indication (bolded) of the current offer amount 635. The set of offer amount buckets 630 includes indications (horizontal bars) of a frequency of acceptance of different offer amount buckets in the set of offer amount buckets 630.

The current offer amount 635 shows an amount of the current offer in price per hour. The current offer amount 635 and the current route represent the current offer. The offer generator can generate multiple offers (i.e., multiple combinations of routes and offer amounts) to present to the current driver. After presenting a set number of offers to the current driver, the offer generator can present offers to a different driver of the set of drivers 620. The current driver can be randomly selected from the set of drivers 620. The current driver can be selected from the set of drivers based on a probability of the current driver checking the market at the current time. The current driver can be selected based on a probabilistic model that is executed using as input the current time and characteristics of the set of drivers 620 to output the current driver. In this way, the current driver can more accurately reflect driver behavior, such as when drivers check the market.

The market clearance indicator 650 indicates a percentage of the set of routes 610 that have been accepted. The time period indicator 660 indicates a percentage of the time period that has elapsed. The offer generator can take into account the market clearance and elapsed time in generating offers.

FIG. 6B is the user interface 600 of FIG. 6A at a second time, after the first time, as reflected in the time period indicator 660. At the second time, the market is cleared, and the time period has not ended, indicating that the offer generator cleared the market within the time period. As time has progressed, a greater percentage of the set of routes 610 were accepted until all of the routes were accepted, as reflected in the colors of the set of routes 610 and the market clearance indicator 660. Accordingly, a greater number of the set of drivers 620 have accepted offers, as reflected in the colors of the set of drivers 620. As there are more drivers in the set of drivers 620 than routes in the set of routes 610, not all of the drivers in the set of drivers 620 have accepted routes, meaning the set of driver 620 were competing against each other to accept the set of routes 610.

FIG. 7 is an example chart 700 showing market clearance performance of a trained offer generator relative to a baseline. The offer generator may be the offer generator 310 of FIG. 3 and/or the offer generator 210 of FIG. 2. The chart 700 shows percentage of market clearance over time relative to a time period (i.e., percentage of time period elapsed). The chart 700 includes offer generator performance 710 and baseline performance 720. The baseline performance 720 may be performance of an offer generation approach that increases offer amounts proportional to a number of remaining offers and elapsed time. The offer generator performance 710 may be higher than the baseline performance 720 for a portion of the elapsed time, indicating that the offer generator clears a higher percentage of the market earlier than the baseline.

The chart 700 is an example comparing performance of a specific offer generator to the baseline. Different training approaches and different training data may result in varied performance.

FIG. 8 is an example chart showing price performance of a trained offer generator relative to a baseline. The offer generator may be the offer generator 310 of FIG. 3 and/or the offer generator 210 of FIG. 2. The chart 800 shows offer price, as measure in dollars per hour (similar to the set of offer amount buckets 530 and 630, of FIGS. 5A and 6A, respectively) over time relative to a time period (i.e., percentage of time period elapsed). The chart 800 includes offer generator performance 810 and baseline performance 820. The baseline performance 820 may be performance of an offer generation approach that increases offer amounts proportional to a number of remaining offers and elapsed time. The offer generator performance 810 may be higher than the baseline performance 820 for a first, earlier portion of the elapsed time and lower than the baseline performance 820 for a second, later portion of the elapsed time, indicating that the offer generator generates offers with higher offer amounts earlier in the time period and lower offer amounts later in the time period.

The chart 800 is an example comparing performance of a specific offer generator to the baseline. Different training approaches and different training data may result in varied performance.

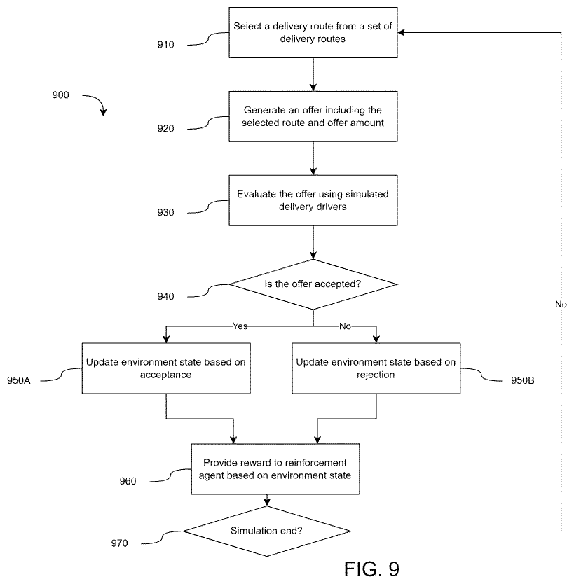

FIG. 9 is a flow diagram of an example method 900 for training a reinforcement agent to generate package delivery offers using simulated delivery drivers. The method 900 may include more, fewer, or different operations than shown. One or more operations may be performed in the order shown, in a different order, and/or concurrently.

At operation 910, a delivery route is selected from a set of delivery routes. The selection of the delivery route can be performed using various criteria, such as route length, expected duration, or package density. In some implementations, the delivery route can be selected based on historical performance data of similar routes. For example, a delivery route with a high historical acceptance rate may be selected. In another example, a delivery route that optimizes for both distance and number of deliveries may be chosen. The delivery route can be selected by a reinforcement agent, which is a type of machine learning model that learns through interaction with an environment. In some implementations, the reinforcement agent randomly selects the delivery route from the set of delivery routes. In some implementations, the reinforcement agent selects the delivery route based on a length, location, or number of packages of the delivery route. In some implementations, the reinforcement agent selects all of the delivery routes of the set of delivery routes to generate offers of all of the delivery routes of the set of delivery routes in parallel.

At operation 920, an offer is generated including the selected route and offer amount. The offer amount can be determined based on multiple factors, such as the route characteristics, time of day, or current market conditions. In some implementations, the offer amount can be calculated using a pricing model that takes into account driver preferences and historical acceptance rates. For example, the offer amount may be increased for routes during peak traffic hours. In another example, the offer amount may be adjusted based on the current supply of available drivers in the area.

In some implementations, generating the offer at operation 920 can include selecting a price bucket to pair with the selected delivery route. The reinforcement agent can choose from a set of predefined price buckets, each representing a range of offer amounts or a specific price point. For example, the reinforcement agent may select from price buckets such as $15-20 per hour, $20-25 per hour, or $25-30 per hour, among others. The offer amount can be calculated by multiplying an expected duration of the delivery route by the selected price bucket. The selection of a price bucket can be based on various factors, such as the characteristics of the selected route, current market conditions, or historical acceptance rates for similar offers. In an example, for a delivery route during peak hours or in a high-demand area, the reinforcement agent may choose a higher price bucket to increase the likelihood of offer acceptance. The pairing of a selected price bucket with the delivery route allows the reinforcement agent to generate offers that balance competitive pricing with driver incentives. The pairing of price buckets with delivery routes allows for consistent analysis of offers using a single metric of dollars per hour.

At operation 930, the offer is evaluated using simulated delivery drivers. The simulated delivery drivers can be programmed with various behavioral models to mimic real-world driver decision-making processes. In some implementations, the simulated delivery drivers can consider factors such as the offer amount, route difficulty, and their own simulated schedules when evaluating the offer. For example, a simulated driver may be more likely to accept an offer for a route close to their current location. In another example, a simulated driver may reject an offer if the simulated time conflicts with their pre-programmed availability.

At operation 940, a determination is made as to whether the offer is accepted. The acceptance or rejection of the offer can be based on the evaluation performed by the simulated delivery drivers. In some implementations, the determination can involve a probabilistic model that calculates the likelihood of offer acceptance based on multiple simulated driver responses. For example, if a majority of simulated drivers accept the offer, it may be determined as accepted. In another example, the offer may be considered accepted if it meets or exceeds a predetermined acceptance threshold across all simulated drivers.

At operation 950A, if the offer is accepted, the environment state is updated based on acceptance. The environment state can include various parameters such as the number of accepted offers, remaining unassigned routes, and current market conditions. In some implementations, updating the environment state can involve adjusting the availability of both the accepted route and the simulated driver who accepted the offer. For example, the accepted route may be removed from the pool of available routes. In another example, the simulated driver who accepted the offer may have their availability updated to reflect the time commitment of the accepted route.

At operation 950B, if the offer is not accepted, the environment state is updated based on rejection. The update can involve modifying parameters related to the rejected offer, such as increasing a counter for the number of rejections for that particular route. In some implementations, the rejection can trigger adjustments to the offer generation process for future offers. For example, the offer amount for the rejected route may be increased in subsequent iterations. In another example, the rejection may cause the route to be flagged for re-evaluation or potential modification.

At operation 960, a reward is provided to the reinforcement agent based on the environment state. The reward can be calculated based on various factors such as the number of accepted offers, the efficiency of route assignments, or the overall cost of completed deliveries. In some implementations, the reward can be a composite score that balances multiple objectives, such as maximizing market clearance while minimizing offer amounts. For example, a higher reward may be given if all routes are assigned with minimal increases to offer amounts. In another example, the reward may be reduced if many high-value offers were necessary to clear the market.

At operation 970, a determination is made as to whether the simulation has ended. The end condition for the simulation can be based on various criteria, such as a predetermined number of iterations, achievement of a target market clearance rate, or expiration of a simulated time period. In some implementations, multiple end conditions can be evaluated simultaneously. For example, the simulation may end when either all routes have been assigned or a maximum number of offer generations has been reached. In another example, the simulation may continue until a stable state is achieved, where subsequent iterations produce minimal changes to the environment state.

In some implementations, the method 900 can include selecting the set of simulated drivers from a plurality of simulated delivery drivers. The selection of the set of simulated drivers can be performed based on various criteria to create a representative sample of driver behaviors and characteristics or to simulate when drivers evaluate offers. For example, the set of simulated drivers can be selected to include a diverse range of driver preferences, availability patterns, and historical performance metrics. The selection process can involve using a probabilistic model that takes into account factors such as time of day, day of the week, and current market conditions to determine which simulated drivers are likely to be active and available for offer evaluation.

In some implementations, selecting the set of simulated drivers from the plurality of simulated delivery drivers can include executing a probabilistic model using as input a time step of the simulated environment and characteristics of the plurality of simulated delivery drivers. The probabilistic model can be designed to mimic real-world driver behavior patterns, such as the likelihood of drivers checking for available offers at different times of day. For example, the model can assign higher probabilities to drivers being active during peak delivery hours or on days with historically high delivery volumes. The characteristics of the plurality of simulated delivery drivers can include factors such as preferred working hours, vehicle type, delivery experience level, and historical acceptance rates for different types of offers.

In some implementations, the method 900 can further include selecting a new set of simulated delivery drivers from the plurality of delivery drivers for each time step of the simulated environment. This dynamic selection process can allow for a more realistic simulation of the changing pool of available drivers over time. For example, at each time step, some simulated drivers may become unavailable due to accepting offers or ending their simulated work shifts, while others may become available as they start their simulated work periods. The selection of the new set of simulated delivery drivers can be based on the current state of the simulated environment, including factors such as the number of remaining unassigned routes, the current market clearance rate, and the time elapsed in the simulation. This approach can provide a more accurate representation of the fluctuating driver pool that an offer generator may encounter in real-world scenarios.

In some implementations, the term “route” may be referred to as a “route of provisioning tasks.” This terminology can encompass a broader range of activities beyond traditional package delivery. A route of provisioning tasks may include a sequence of locations or actions where various services or goods are provided, such as food delivery, equipment installation, or on-site technical support.

The term “offer” may correspond to a route-value vector in certain aspects of the system. A route-value vector can represent a multidimensional description of an offer, combining information about the route itself with its associated value or compensation. This vector may include components such as the route's geographic coordinates, estimated duration, difficulty level, and the monetary value assigned to completing the route.

In some cases, a “delivery driver” may be referred to as a “provisioning agent.” This broader term can encompass individuals or entities responsible for executing the provisioning tasks along a route. Provisioning agents may include not only traditional delivery drivers but also technicians, service providers, or any personnel tasked with fulfilling the requirements of a given route. This terminology allows for a more flexible interpretation of the role, accommodating various types of service provision beyond package delivery.

The method for training a reinforcement agent to generate route-value vectors can be implemented in various ways to efficiently exhaust a set of routes of provisioning tasks within a predetermined time period. The reinforcement agent can select a route of provisioning tasks from a set of routes of provisioning tasks based on various criteria, such as route length, expected duration, or package density. In some implementations, the reinforcement agent can select the route based on historical performance data of similar routes. For example, the reinforcement agent can select a route with a high historical acceptance rate or a route that optimizes for both distance and number of deliveries.

The reinforcement agent can generate a route-value vector including the selected route of provisioning tasks and a value. The value can be determined based on multiple factors, such as route characteristics, time of day, or current market conditions. In some implementations, the value can be calculated using a pricing model that takes into account provisioning agent preferences and historical acceptance rates. For example, the value can be increased for routes during peak traffic hours or adjusted based on the current supply of available provisioning agents in the area.

The generated route-value vector can be evaluated using a set of simulated provisioning agents within a simulated environment. The simulated provisioning agents can be programmed with various behavioral models to mimic real-world decision-making processes. In some implementations, the simulated provisioning agents can consider factors such as the value, route difficulty, and their own simulated schedules when evaluating the route-value vector. For example, a simulated provisioning agent can be more likely to select for execution a route-value vector for a route close to their current location.

The state of the simulated environment can be updated based on whether the set of simulated provisioning agents reject the generated route-value vector or at least one simulated provisioning agent selects the generated route-value vector for execution. The environment state can include various parameters such as the number of selected route-value vectors, remaining unassigned routes, and current market conditions. In some implementations, updating the environment state can involve adjusting the availability of both the accepted route and the simulated provisioning agent who selected the route-value vector for execution.

A reward can be generated for the reinforcement agent based on the state of the simulated environment. The reward can be calculated based on various factors such as the number of accepted route-value vectors, the efficiency of route assignments, or the overall cost of completed provisioning tasks. In some implementations, the reward can be a composite score that balances multiple objectives, such as maximizing market clearance while minimizing route-value vector values.

The parameters of the reinforcement agent can be updated using the generated reward. This update can allow the reinforcement agent to learn from the outcomes of its decisions and improve its performance over time. In some implementations, the update can involve adjusting the weights of different factors considered in the route selection and value determination processes.

The method can include selecting the set of simulated provisioning agents from a plurality of simulated provisioning agents. This selection can be performed based on various criteria to create a representative sample of provisioning agent behaviors and characteristics. In some implementations, the selection can involve using a probabilistic model that takes into account factors such as time of day, day of the week, and current market conditions to determine which simulated provisioning agents are likely to be active and available for route-value vector evaluation.

The method can also include selecting a new set of simulated provisioning agents from the plurality of provisioning agents for each time step of the simulated environment. This dynamic selection process can allow for a more realistic simulation of the changing pool of available provisioning agents over time. For example, at each time step, some simulated provisioning agents can become unavailable due to accepting route-value vectors or ending their simulated work shifts, while others can become available as they start their simulated work periods.

The various illustrative logical blocks, circuits, modules, routines, and algorithm steps described in connection with the embodiments disclosed herein can be implemented as electronic hardware, or combinations of electronic hardware and computer software. To clearly illustrate this interchangeability, various illustrative components, blocks, modules, and steps have been described above generally in terms of their functionality. Whether such functionality is implemented as hardware, or as software that runs on hardware, depends upon the particular application and design constraints imposed on the overall system. The described functionality can be implemented in varying ways for each particular application, but such implementation decisions should not be interpreted as causing a departure from the scope of the disclosure.

Moreover, the various illustrative logical blocks and modules described in connection with the embodiments disclosed herein can be implemented or performed by a machine, such as a general purpose processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A control processor can synthesize a model for an FPGA. For example, the control processor can synthesize a model for logical programmable gates to implement a tensor array and/or a pixel array. The control channel can synthesize a model to connect the tensor array and/or pixel array on an FPGA, a reconfigurable chip and/or die, and/or the like. A general purpose processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances, where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A method for training a reinforcement agent to generate route-value vectors to efficiently exhaust a set of routes of provisioning tasks within a predetermined time period, comprising:
selecting, by the reinforcement agent, a route of provisioning tasks from a set of routes of provisioning tasks;
generating, by the reinforcement agent, a route-value vector including the selected route of provisioning tasks and a value;
evaluating, using a set of simulated provisioning agents within a simulated environment, the generated route-value vector to select for execution the generated route-value vector;
responsive to the set of simulated provisioning agents rejecting the generated route-value vector or at least one simulated provisioning agent of the set of simulated provisioning agents selecting the generated route-value vector for execution, updating a state of the simulated environment;
generating a reward for the reinforcement agent based on the state of the simulated environment; and
updating parameters of the reinforcement agent using the generated reward.

2. The method of claim 1, wherein the reward includes a reward portion corresponding to a first characteristic of the state of the simulated environment and a punishment portion corresponding to a second characteristic of the simulated environment.

3. The method of claim 1, wherein the reward is based on one or more characteristics of the state of the simulated environment including the route-value vector amount, whether the route-value vector was selected for execution, a percentage of the set of route of provisioning tasks that have been selected for execution, and time steps within the simulated environment.

4. The method of claim 1, further comprising:
generating, by the reinforcement agent, route-value vectors;
evaluating, using the plurality of simulated provisioning agents, the generated route-value vectors; and
updating the state of the simulated environment until the state of the simulated environment reaches a predetermined state.

5. The method of claim 4, wherein providing the reward to the reinforcement agent based on the state of the simulated environment includes providing the reward to the reinforcement agent after the state of the simulated environment reaches the predetermined state based on the predetermined state of the environment.

6. The method of claim 4, wherein the predetermined state includes at least one of a state of all the route of provisioning tasks of the set of route of provisioning tasks being selected for execution in the generated route-value vectors and a time step of the simulated environment reaching an end time step.

7. The method of claim 6, wherein the end time step corresponds to an end of the predetermined time period.

8. The method of claim 1, further comprising selecting the set of simulated provisioning agents from a plurality of simulated provisioning agents.

9. The method of claim 8, wherein selecting the set of simulated provisioning agents from the plurality of simulated provisioning agents includes executing a probabilistic model using as input a time step of the simulated environment and characteristics of the plurality of simulated provisioning agents.

10. The method of claim 8, further comprising selecting a new set of simulated provisioning agents from the plurality of provisioning agents for each time step of the simulated environment.

11. A non-transitory, computer-readable medium including instructions which, when executed by one or more processors, cause the one or more processors to:
select, by a reinforcement agent, a route of provisioning tasks from a set of route of provisioning tasks;
generate, by the reinforcement agent, an route-value vector including the selected route of provisioning tasks and an route-value vector amount;
evaluate, using a plurality of simulated provisioning agents within a simulated environment, the generated route-value vector to accept or reject the generated route-value vector;
responsive to the plurality of simulated provisioning agents rejecting the generated route-value vector or at least one simulated delivery driver of the plurality of simulated provisioning agents accepting the generated route-value vector, update a state of the simulated environment; and
provide a reward to the reinforcement agent based on the state of the simulated environment.

12. The non-transitory, computer-readable medium of claim 11, wherein the reward includes a reward portion corresponding to a first characteristic of the state of the simulated environment and a punishment portion corresponding to a second characteristic of the simulated environment.

13. The non-transitory, computer-readable medium of claim 11, wherein the reward is based on one or more characteristics of the state of the simulated environment including the route-value vector amount, whether the route-value vector was selected for execution, a percentage of the set of route of provisioning tasks that have been selected for execution, and time steps within the simulated environment.

14. The non-transitory, computer-readable medium of claim 11, wherein the instructions cause the one or more processors to:
generate, by the reinforcement agent, route-value vectors;
evaluate, using the plurality of simulated provisioning agents, the generated route-value vectors; and
update the state of the simulated environment until the state of the simulated environment reaches a predetermined state.

15. The non-transitory, computer-readable medium of claim 14, wherein the instructions cause the one or more processors to provide the reward to the reinforcement agent based on the state of the simulated environment after the state of the simulated environment reaches the predetermined state and based on the predetermined state of the environment.

16. The non-transitory, computer-readable medium of claim 14, wherein the predetermined state includes at least one of a state of all the route of provisioning tasks of the set of route of provisioning tasks being selected for execution in the generated route-value vectors and a time step of the simulated environment reaching an end time step.

17. The non-transitory, computer-readable medium of claim 16, wherein the end time step corresponds to an end of the predetermined time period.

18. The non-transitory, computer-readable medium of claim 11, further comprising selecting the set of simulated provisioning agents from a plurality of simulated provisioning agents.

19. The non-transitory, computer-readable medium of claim 18, wherein selecting the set of simulated provisioning agents from the plurality of simulated provisioning agents includes executing a probabilistic model using as input a time step of the simulated environment and characteristics of the plurality of simulated provisioning agents.

20. The non-transitory, computer-readable medium of claim 18, further comprising selecting a new set of simulated provisioning agents from the plurality of provisioning agents for each time step of the simulated environment.
